(19) United States
(12) Patent Application Publication
(10) Pub. No.: US 2007/0243814 A1
(43) Pub. Date: Oct. 18, 2007

(54) Enclosure unit and electronic apparatus

(75) Inventor: Eiji Makabe, Kawasaki (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 11/387,763

(22) Filed: Mar. 24, 2006

(51) Int. Cl. H05K 5/00

(52) U.S. Cl. 454/184

(57) ABSTRACT

The enclosure unit allows airflow in a first direction within a hollow space inside a ducts placed in an enclosure. The enclosure unit also allows establishment of a first flow passage surrounded by the inside surface of the enclosure. The first flow passage extends in a second direction intersecting the first direction up to the ducts. Airflow runs in the first flow passage in the second direction. Moreover, the enclosure unit also allows establishment of a second flow passage in the second direction between the ducts. Airflow is allowed to run into the second flow passage from the first flow passage. The airflow runs straight in the second direction in the enclosure.

### BACKGROUND OF THE INVENTION

1. Field of the Invention

The present invention relates to an enclosure unit utilized in an electronic apparatus such as a server computer, for example.

2. Description of the Prior Art

Power source units are placed on the upper rack of the enclosure of a server computer, for example. Each of the power source units includes a duct extending from the front side toward the back side of the enclosure. A fan is incorporated in the power source unit. The fan serves to generate airflow running within the duct in the horizontal direction in parallel with the floor. The airflow cools down the power source unit. The power source unit is in this manner prevented from a rise in temperature.

Fans are placed on the middle rack of the enclosure. System board units are placed on the lower rack of the enclosure. Each of the system board units includes a system board standing upright in the vertical direction perpendicular to the floor. The fans serve to generate airflow running in the vertical direction from the bottom of the enclosure toward the top of the enclosure. The airflow absorbs heat from electronic circuit elements on the system boards. The system boards are thus cooled down.

The airflow from the fan collides against the bottoms of the ducts of the power source units. This results in a change in the direction of the airflow. The airflow runs toward the back of the enclosure along the bottoms of the power source units, for example. Such a change in the direction of the airflow causes an increase in the pressure loss of the airflow. This hinders the airflow in the enclosure in the vertical direction. The system boards cannot sufficiently be cooled.

### SUMMARY OF THE INVENTION

It is accordingly an object of the present invention to provide an enclosure unit and an electronic apparatus capable of reducing hindrance to airflow.

According to a first aspect of the present invention, there is provided an enclosure unit comprising: an enclosure; ducts placed in the enclosure, the ducts each defining a hollow space extending in a first direction; a first flow passage surrounded by the inside surface of the enclosure, the first flow passage extending in a second direction intersecting the first direction up to the ducts; and a second flow passage defined between the adjacent ones of the ducts, the second flow passage extending in the second direction from the first flow passage.

The enclosure unit allows establishment of an air flow passage in the first direction within the hollow space inside the duct placed in the enclosure. The enclosure unit also allows establishment of the first flow passage surrounded by the inside surface of the enclosure. The first flow passage extends in the second direction intersecting the first direction up to the ducts. Airflow runs through the first flow passage in the second direction. Since airflow within the ducts is completely isolated from the airflow of the second direction, the airflow within the ducts is prevented from being interfered with the airflow of the second direction. The airflow can thus reliably run in the first direction.

Moreover, the enclosure unit allows establishment of the second flow passage extending in the second direction between the adjacent ones of the ducts. The airflow is thus allowed to run into the second flow passage from the first flow passage. The airflow is allowed to run straight in the vertical direction in the enclosure. Airflow is thus prevented to the utmost from being interfered. This results in a reduction in the pressure loss of the airflow running in the first flow passage. The airflow of a sufficient amount can be realized in the enclosure.

The enclosure unit allows the air flow passage in the first direction to intersect with the air flow passage in the second direction. The enclosure can thus be reduced in size as compared with an enclosure including flow passages in different directions side by side.

The enclosure unit may further comprise a third flow passage extending in the enclosure in the first direction from the first flow passage in parallel with the ducts. The airflow runs into the third flow passage from the first flow passage. A larger amount of airflow is allowed to flow into the first and third flow passages from the first flow passage. This results in a reduction in the pressure loss of the airflow in the first flow passage. The enclosure unit may additionally allow establishment of the second flow passage between the inside surface of the enclosure and the ducts.

According to a second aspect of the present invention, there is provided an enclosure unit comprising: an enclosure; a duct placed in the enclosure, the duct defining a hollow space extending in a first direction; a first flow passage surrounded by the inside surface of the enclosure, the first flow passage extending in a second direction intersecting the first direction up to the duct; and a second flow passage defined at least between the duct and the inside surface of the enclosure, the second flow passage extending in the second direction from the first flow passage.

The enclosure unit allows establishment of an air flow passage in the first direction within the hollow space inside the duct placed in the enclosure in the same manner as mentioned above. The enclosure unit also allows establishment of the first flow passage surrounded by the inside surface of the enclosure. The first flow passage extends in the second direction intersecting the first direction up to the duct. Airflow runs through the first flow passage in the second direction. Since airflow within the duct is completely isolated from the airflow of the second direction, the airflow within the duct is prevented from being interfered with the airflow of the second direction. The airflow can thus reliably run in the first direction.

Moreover, the enclosure unit allows establishment of the second flow passage extending in the second direction between the inside surface of the enclosure and the duct. The airflow is thus allowed to run into the second flow passage from the first flow passage. The airflow is allowed to run straight in the vertical direction in the enclosure. Airflow is thus prevented to the utmost from being interfered. This results in a reduction in the pressure loss of the airflow running in the first flow passage. The airflow of a sufficient amount can be realized in the enclosure.

According to a third aspect of the present invention, there is provided an electronic apparatus comprising: an enclosure; power source units placed in the enclosure at an uppermost position, the power source units each extending in the horizontal direction; an electronic component unit placed at a position below the power source unit, the electronic component unit including a substrate extending in the vertical direction; a fan placed at a position below the power source unit, the fan generating airflow in the vertical direction of the enclosure; and a gap formed at least either between the power source units and the inside surface of the enclosure or between the adjacent ones of the power source units arranged in parallel with each other in the horizontal direction.

The power source units extend in the horizontal direction at the uppermost position in the enclosure. The electronic component unit and the fan are placed below the power source units. The substrate extends in the vertical direction in the electronic component unit. The fan serves to generate airflow in the vertical direction of the enclosure. The airflow runs along the substrate of the electronic component unit. The airflow absorbs heat from the substrate. A gap is formed at least either between the power source unit and the inside surface of the enclosure or between the adjacent ones of the power source units arranged in parallel with each other in the horizontal direction. The airflow is allowed to run straight through the gap in the vertical direction. Airflow is thus prevented to the utmost from being interfered. This results in a reduction in the pressure loss of the airflow running in the vertical direction. The airflow of a sufficient amount can be realized in the enclosure. Since airflow within the power source units is completely isolated from the airflow of the vertical direction, the airflow within the power source units is prevented from being interfered with the airflow of the vertical direction. The airflow can thus reliably run in the horizontal direction.

An opening may be formed in the top surface of the enclosure at least at a position corresponding to the position of the gap. The opening enables a discharge of the airflow passing through the gaps. The power source unit may include a fan generating airflow in the horizontal direction. In this case, an opening may be formed in the top surface of the enclosure at least at a position corresponding to the position of the gap.

According to a fourth aspect of the present invention, there is provided an electronic apparatus comprising: an enclosure; a first unit placed in the enclosure, the first unit allowing airflow to run in the horizontal direction; and a second unit placed in the enclosure, the second unit allowing airflow to run in the vertical direction. In this case, the first unit is placed at the uppermost or lowermost position of the enclosure.

The electronic apparatus allows airflow to run in the horizontal direction within the first unit. The second unit enables airflow in the vertical direction. The electronic apparatus allows the air flow passage in the horizontal direction to intersect with the air flow passage in the vertical direction within the enclosure. The enclosure can thus be reduced in size as compared with an enclosure including flow passages in different directions side by side. Since the first unit is placed at the uppermost or lowermost position of the enclosure, the flow passage is prevented from being divided in the second unit. Airflow is allowed to run in the vertical direction regardless of the position of the first unit. The electronic apparatus may further comprise a fan generating airflow running in the vertical direction.

### BRIEF DESCRIPTION OF THE DRAWINGS

The above and other objects, features and advantages of the present invention will become apparent from the following description of the preferred embodiment in conjunction with the accompanying drawings, wherein:

FIG. 1 is a perspective view schematically illustrating a server computer as an example of an electronic apparatus according to an embodiment of the present invention;

FIG. 2 is an enlarged partial sectional view of the server computer for schematically illustrating the structure of power source units;

FIG. 3 is a front view schematically illustrating the server computer; and

FIG. 4 is an enlarged partial sectional view of the server computer for schematically illustrating flow passages for airflow.

### DESCRIPTION OF THE PREFERRED EMBODIMENT

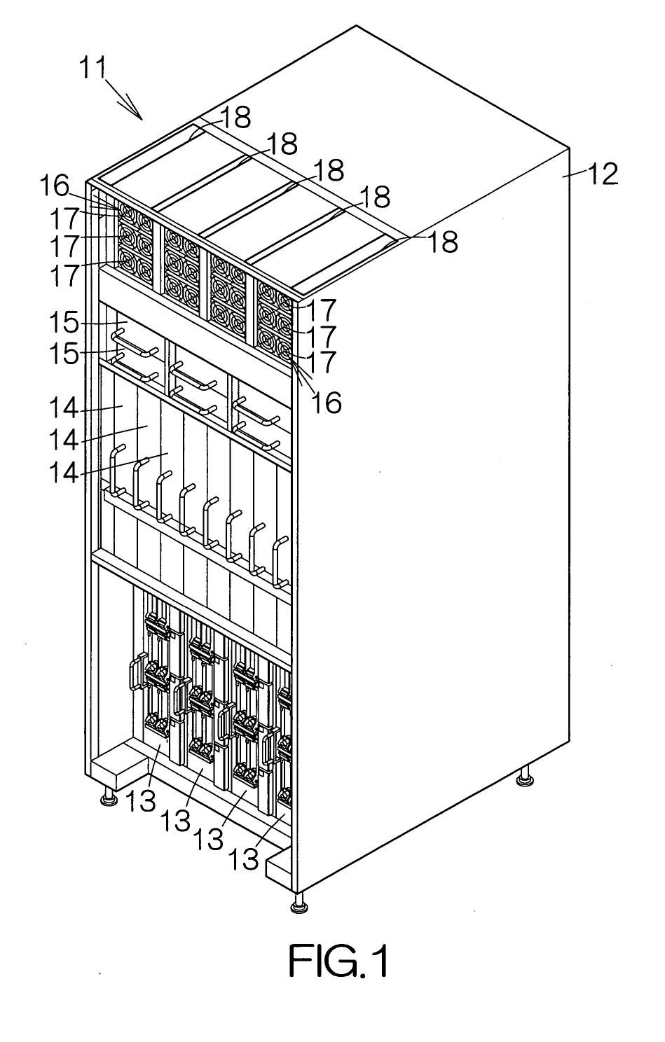

FIG. 1 schematically illustrates a server computer 11 as an example of an electronic apparatus according to an embodiment of the present invention. The server computer 11 includes an enclosure 12. Electronic component units, namely input/output units 13, are mounted on the lower rack of the enclosure 12. PCI boards are respectively incorporated in the input/output units 13, for example. LAN cables are coupled to the PCI boards, for example. The PCI boards within the input/output units 13 stand upright in the vertical direction perpendicular to the floor.

Electronic component units, namely system board units 14, are mounted on the middle rack of the enclosure 12. System boards are respectively incorporated in the system board units 14. Electronic circuit element such as a central processing unit (CPU) and an a memory are mounted on the individual system board, for example. The CPU executes various kinds of processing based on a software program and/or data, temporarily stored in the memory, for example. The system boards stand upright in the vertical direction within the system board units 14.

Fan units 15 are mounted on the upper rack of the enclosure 12. The individual fan unit 15 includes axial flow fans, for example. Rotors are incorporated in the axial flow fans, respectively. The rotors are driven to rotate in the fan units 15 so as to generate airflow within the enclosure 12. The rotation axes of the rotors are set to extend in the vertical direction. The generated airflow thus runs in the vertical direction from the bottom plate of the enclosure toward the top panel of the enclosure 12, for example.

Power source unit sets 16 are mounted on the uppermost rack of the enclosure 12. The power source unit sets 16, four rows in this case, are arranged in the horizontal direction parallel to the floor, for example. Each of the power source unit sets 16 includes power source units 17 arranged in three tiers in the vertical direction, for example. The power source units 17 are designed to extend in the horizontal direction from the front side of the enclosure 12 toward the back side of the enclosure 12. The power source units 17 serve to transform the alternating current to the direct current. The alternating current is supplied from an outlet, for example.

Air outlets 18 are formed in the top panel of the enclosure 12. The air outlets 18 are designed to extend straight in the horizontal direction from the front edge toward the rear edge of the top panel. Here, the air outlets 18 may extend in parallel with one another. The air outlets 18 are formed at positions corresponding to the positions of gaps defined between the adjacent ones of the power source unit sets 16, as described later in detail. The air outlets 18 are also formed at positions corresponding to gaps defined between the power source unit sets 17 and the inside surface of the enclosure 12, as described later in detail. The airflow generated at the fan units 15 is discharged through the air outlets 18. An air inlet or inlets, not shown, are formed in the bottom plate of the enclosure 12. A fresh air is introduced into the enclosure 12 through the air inlet or inlets.

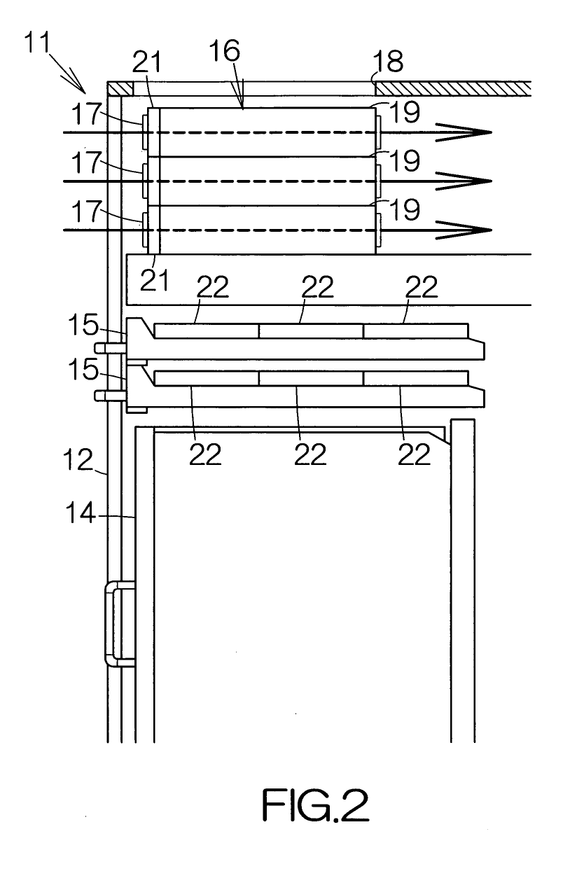

FIG. 2 is an enlarged partial sectional view schematically illustrating the upper part of the server computer 11. Each power source unit 17 includes a duct 19 defining a hollow space extending from the front side of the enclosure toward the back side of the enclosure 12, as shown in FIG. 2. The duct 19 may extend in a second direction in parallel with the floor, namely the horizontal direction. A fan 21 is incorporated within the hollow space of the duct 19. The fan 21 serves to introduce a fresh air through the front end of the duct 19. The ducts 19 in this manner enable airflow in the horizontal direction from the front side of the server computer 11 toward the back side of the server computer 11. Each of the fan unit 15 includes three axial flow fans 22, for example.

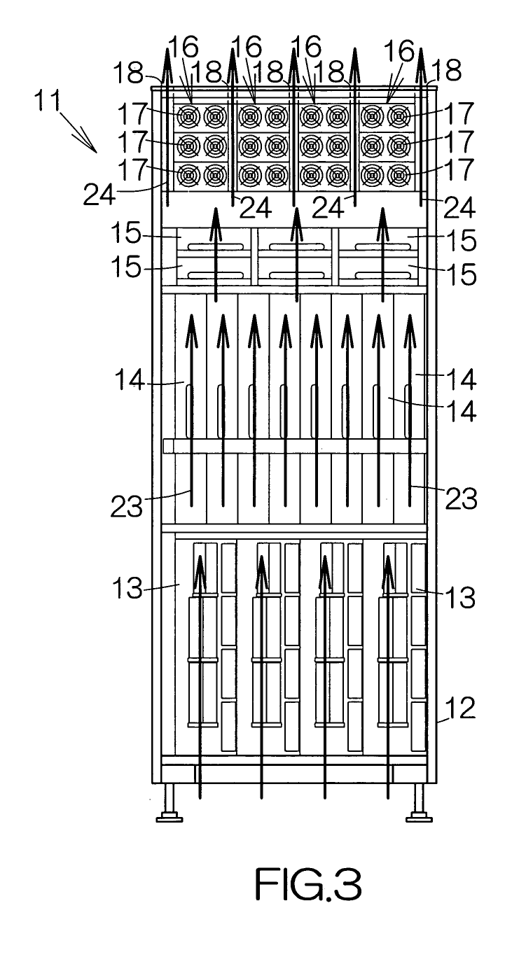

FIG. 3 is a front view of the server computer 11. FIG. 3 schematically illustrates the flow paths of the airflow. The PCI boards stand upright in the vertical direction within the input/output units 13 as described above. The system boards likewise stand upright in the vertical direction within the system board units 14 as described above. The fan units 15 thus allow airflow to run in the enclosure 12 in the vertical direction between the adjacent ones of the PCI boards and the adjacent ones of the system boards. First flow passages 23 are in this manner defined in the enclosure 12. The first flow passages 23 are surrounded by the inside surface of the enclosure 12. The first flow passages 23 extend in the vertical direction from the air inlet or inlets of the bottom of the enclosure 12 up to the power source unit sets 16.

The individual power source unit set 16 is spaced from the adjacent power source unit set or sets 16 at a predetermined interval in the enclosure 12. Gaps are formed between the adjacent ones of the power source unit sets 16, respectively. The power source units 16 are spaced from the inside surface of the enclosure 12 at a predetermined interval. Gaps are in this manner formed between the outermost power source units 16 and the inside surface of the enclosure 12. The gaps serve to provide second flow passages 24 extending in the vertical direction. The first flow passages 23 are connected to the second flow passages 24. The second flow passages 24 lead to the aforementioned air outlets 18.

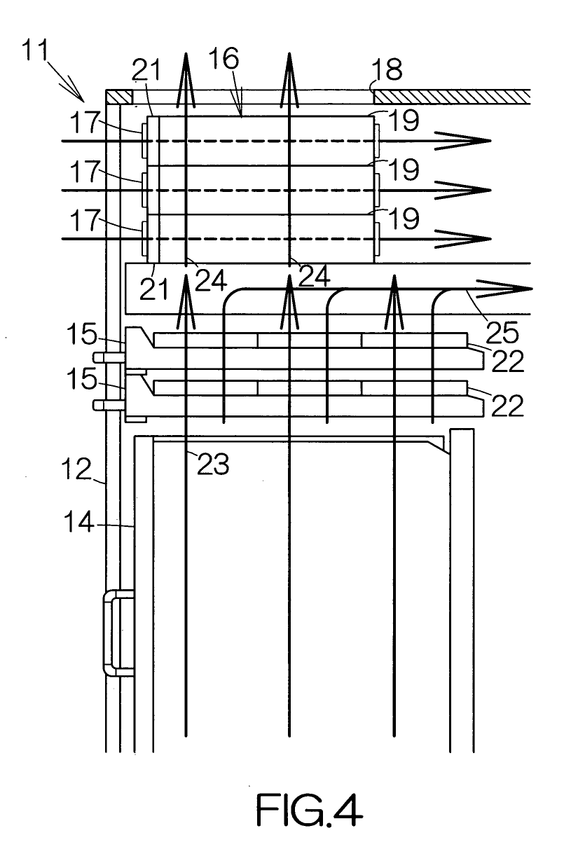

FIG. 4 is an enlarged partial sectional view of the upper part of the server computer 11. FIG. 3 schematically illustrates the flow paths of the airflow. A third flow passage 25 is defined between the bottoms of the ducts 19 of the power source units 17 and the fan units 15, as shown in FIG. 4. The third flow passage 25 extends in parallel with the ducts 19. Here, the third flow passage 25 extends in the horizontal direction from the front side of the enclosure 12 toward the back side of the enclosure 12. The third flow passage 25 is designed to lead to an air outlet or outlets formed in the back panel of the enclosure 12, for example. The aforementioned first flow passages 23 are connected to the third flow passage 25. The enclosure 12, the ducts 19, and the first and second flow passages 23, 24 in combination serve as an enclosure unit of the present invention.

Now, assume that the fan units 15 generate airflow in the enclosure 12. The rotors of the axial flow fans 22 are driven to rotate in the fan units 15 for generating airflow. A fresh air is introduced into the enclosure 12 through the air inlet or inlets in the bottom plate of the enclosure 12. Airflow thus runs in the vertical direction through the first flow passages 23. The airflow absorbs heat from the electronic circuit elements on the input/output units 13 and the system board units 14. The electronic circuit elements are thus prevented from a rise in temperature. The airflow then passes through the fan units 15.

The airflow runs into the second flow passages 24 along the vertical direction from the first flow passages 23. The airflow is then discharged outside the enclosure 12 through the air outlets 18. Some of the airflow from the first flow passages 23 collides against the bottoms of the ducts 19. This results in a change in the direction of the airflow. The airflow is thus forced to run into the third flow passage 25 in the horizontal direction. The airflow is then discharged outside the enclosure 12 through the air outlet or outlets of the back panel of the enclosure 12.

The fans 21 serve to generate airflow running in the horizontal direction through the ducts 19 in the power source units 17 from the front ends of the ducts 19 toward the rear ends the ducts 19. The airflow absorbs heat from the power source units 17. The power source units 17 are thus prevented from a rise in temperature. The airflow is discharged into the inside space of the enclosure 12 through the rear ends of the ducts 19. The airflow is then discharged outside the enclosure 12 through the air outlet or outlets of the back panel of the enclosure 12.

The server computer 11 allows airflow to run in the horizontal direction, namely a first direction, within the ducts 19 of the power source units 17. The air flow runs in the enclosure 12 in the vertical direction, namely the second direction, within the first and second flow passages 23, 24. Since the airflow within the ducts 19 is completely isolated from the vertical airflow, the airflow within the ducts 19 is not interfered with the vertical airflow. The airflow is thus reliably allowed to run in the horizontal direction. The power source units 17 can reliably be cooled down. The power source units 17 are reliably prevented from a rise in temperature.

The gaps between the adjacent ones of the power source units 17 and the gaps between the power source units 17 and the inside surface of the enclosure 12 serve as ducts for the vertical airflow. The airflow runs into the second flow passages 24 from the first flow passages 23. The airflow is thus allowed to run in the enclosure 12 straight in the second direction. A reduced amount of the airflow runs into the third flow passage 25 from the first flow passages 23. Airflow is thus prevented to the utmost from being interfered. This results in a reduction in the pressure loss of the airflow running within the first flow passages 23. The airflow of a large amount is allowed to flow out of the first flow passages 23. The airflow of a sufficient amount is thus realized in the enclosure 12. The input/output units 13 and the system board units 14 can sufficiently be cooled down. The server computer 11 is thus allowed to enjoy a higher efficient cooling as compared with a conventional server computer. Here, the interval between the adjacent ones of the power source units 17 and the interval between the power source units 17 and the inside surface of the enclosure 12 may be set large or wide enough to enable airflow of a sufficient amount in the first flow passages 23. It should be noted that the interval may differ from one another as long as airflow of a required amount is established in the gaps in total.

The flow passages for the horizontal airflow are designed to intersect with the flow passages for the vertical airflow in the enclosure 12 of the server computer 11. The enclosure 12 can be reduced in size as compared with an enclosure including the horizontal flow passages and vertical flow passages side by side. In particular, since the power source units 17 are placed on the uppermost rack of the enclosure 12 in the server computer 11, the vertical airflow is allowed to continuously run through the input/output units 13 and the system board units 14. The vertical flow passages are not divided. An efficient airflow can be established in the vertical direction regardless of the location of the power source units 17. It should be noted that the power source units 17 may be placed on the lowermost rack of the enclosure 12.

What is claimed is:

1. An enclosure unit comprising:
an enclosure;
ducts placed in the enclosure, said ducts each defining a hollow space extending in a first direction;
a first flow passage surrounded by an inside surface of the enclosure, said first flow passage extending in a second direction intersecting the first direction up to the ducts; and
a second flow passage defined between adjacent ones of the ducts, said second flow passage extending in the second direction from the first flow passage.

2. The enclosure unit according to claim 1, further comprising a third flow passage extending in the enclosure in the first direction from the first flow passage in parallel with the ducts.

3. The enclosure unit according to claim 1, wherein the second flow passage is defined between the inside surface of the enclosure and the ducts.

4. An enclosure unit comprising:
an enclosure;
a duct placed in the enclosure, said duct defining a hollow space extending in a first direction;
a first flow passage surrounded by an inside surface of the enclosure, said first flow passage extending in a second direction intersecting the first direction up to the duct; and
a second flow passage defined at least between the duct and the inside surface of the enclosure, said second flow passage extending in the second direction from the first flow passage.

5. An electronic apparatus comprising:
an enclosure;
power source units placed in the enclosure at an uppermost position, said power source units each extending in a horizontal direction;
an electronic component unit placed at a position below the power source units, said electronic component unit including a substrate extending in a vertical direction;
a fan placed at a position below the power source units, said fan generating airflow in a vertical direction of the enclosure; and
a gap formed at least either between the power source units and an inside surface of the enclosure or between adjacent ones of the power source units arranged in parallel with each other in a horizontal direction.

6. The electronic apparatus according to claim 5, wherein an opening is formed in a top surface of the enclosure at least at a position corresponding to position of the gap.

7. The electronic apparatus according to claim 5, wherein the power source unit includes a fan inside, said fan generating airflow running in the horizontal direction.

8. The electronic apparatus according to claim 7, wherein an opening is formed in a top surface of the enclosure at least at a position corresponding to position of the gap.

9. An electronic apparatus comprising:
an enclosure;
a first unit placed in the enclosure, said first unit allowing airflow to run in a horizontal direction; and
a second unit placed in the enclosure, said second unit allowing airflow to run in a vertical direction, wherein the first unit is placed at an uppermost or lowermost position of the enclosure.

10. The electronic apparatus according to claim 9, further comprising a fan generating airflow running in the vertical direction.
